(19) United States
(12) Patent Application Publication
(10) Pub. No.: US 2025/0172640 A1
(43) Pub. Date: May 29, 2025

(54) MAGNETIC SENSOR

(71) Applicant: Alps Alpine Co., Ltd., Tokyo (JP)

(72) Inventors: Kanta KIKUCHI, Niigata-ken (JP); Eiji UMETSU, Niigata-ken (JP); Toshihiro KOBAYASHI, Niigata-ken (JP)

(21) Appl. No.: 19/036,627

(22) Filed: Jan. 24, 2025

Related U.S. Application Data
(63) Continuation of application No. PCT/JP2023/008061, filed on Mar. 3, 2023.

(30) Foreign Application Priority Data
Aug. 12, 2022 (JP) 2022-128866

(51) Int. Cl. G01R 33/09; H10N 50/10

(52) U.S. Cl. CPC G01R 33/09; H10N 50/10

(57) ABSTRACT

A magnetic sensor includes a magnetoresistance effect element including a pinned magnetic layer, a free magnetic layer, and an intermediate layer formed between the pinned magnetic layer and the free magnetic layer, the magnetoresistance effect element having a sensitivity axis in a first direction, a wiring line disposed in a second direction parallel to a stack direction of the magnetoresistance effect element and intersecting the first direction, the wiring line having a first surface facing the magnetoresistance effect element, and a magnetically permeable section disposed on at least part of a surface of surfaces other than the first surface among surfaces of the wiring line, the magnetically permeable section comprising a ferromagnetic material. The wiring line is disposed such that an induced magnetic field generated when the wiring line is energized is applied to the magnetoresistance effect element in the first direction.

### CLAIM OF PRIORITY

This application is a Continuation of International Application No. PCT/JP2023/008061 filed on Mar. 3, 2023, which claims benefit of Japanese Patent Application No. 2022-128866 filed on Aug. 12, 2022. The entire contents of each application noted above are hereby incorporated by reference.

### BACKGROUND OF THE INVENTION

### 1. Field of the Invention

The present invention relates to a magnetic sensor.

### 2. Description of the Related Art

Japanese Unexamined Patent Application Publication No. 2018-115972 discloses a magnetic sensor including a substrate, a magnetic field sensing unit including a stacked portion disposed on the substrate, the stacked portion including a magnetization free layer whose magnetization changes depending on an external magnetic field, a magnetization pinned layer whose magnetization is fixed in a first direction, and a non-magnetic layer disposed between the magnetization free layer and the magnetization pinned layer, the magnetic field sensing unit being configured to output a signal corresponding to the external magnetic field, and a magnetic field generating section configured to apply a bias magnetic field to the magnetization free layer. When the bias magnetic field is not applied to the magnetization free layer, the magnetization direction of the magnetization free layer is approximately parallel or approximately anti-parallel to the first direction, and the magnetic sensor calculates a component in a second direction of the external magnetic field based on a first output that is an output of the magnetic field sensing unit in a state in which a first bias magnetic field including a positive component in the second direction perpendicular to the first direction in a top view is applied to the magnetization free layer, and a second output that is an output of the magnetic field sensing unit in a state in which a second bias magnetic field including a negative component in the second direction is applied to the magnetization free layer.

In the invention disclosed in Japanese Unexamined Patent Application Publication No. 2018-115972, a specific example of the magnetic field generating section is a wiring line section that is provided in the stacking direction of the stacked portion. An induced magnetic field from the energized wiring line section is applied to the magnetization free layer of the stacked section as a bias magnetic field. An external magnetic field is measured in a state in which the bias magnetic field having a different application direction is applied, and 1/f noise is removed based on the measurement results.

As in the magnetic sensor disclosed in Japanese Unexamined Patent Application Publication No. 2018-115972, when an external magnetic field is measured under an induced magnetic field from the wiring line disposed in the vicinity of the magnetoresistance effect element, it may be difficult to increase the strength of the induced magnetic field by increasing the amount of current flowing through the wiring line due to the small cross-sectional area of the wiring line, the structural difficulty in dissipating Joule heat from the wiring line, or other factors.

In view of the above, the present invention is directed to provide a magnetic sensor capable of efficiently applying an induced magnetic field of a wiring line disposed in the vicinity of a magnetoresistance effect element.

### SUMMARY OF THE INVENTION

A magnetic sensor according to an aspect of the present invention to solve the above-described problems includes a magnetoresistance effect element including a pinned magnetic layer, a free magnetic layer, and an intermediate layer formed between the pinned magnetic layer and the free magnetic layer, the magnetoresistance effect element having a sensitivity axis in a first direction, a wiring line disposed in a second direction parallel to a stack direction of the magnetoresistance effect element and intersecting the first direction, the wiring line having a first surface facing the magnetoresistance effect element, and a magnetically permeable section disposed on at least part of a surface of surfaces other than the first surface among surfaces of the wiring line, the magnetically permeable section comprising a ferromagnetic material. The wiring line is disposed such that an induced magnetic field generated when the wiring line is energized is applied to the magnetoresistance effect element in the first direction.

The magnetically permeable section can function as a magnetic collector for collecting an induced magnetic field from a wiring line and increase the strength of the induced magnetic field to be applied to the magnetoresistance effect element.

In the above-described magnetic sensor, an insulating layer may be disposed between the wiring line and the magnetically permeable section. When the resistivity of the magnetically permeable section is low, the amount of current flowing through the magnetically permeable section increases if no insulating layer is provided, resulting in a relative decrease in the amount of current flowing through the wiring line and a decrease in the strength of the induced magnetic field.

When the insulating layer is provided, it is preferable that the insulating layer be a diffusion suppression layer that suppresses interdiffusion between an element forming the wiring line and an element forming the magnetically permeable section. When the insulating layer suppresses interdiffusion between the wiring line and the magnetically permeable section, the composition of the wiring line and/or the magnetically permeable section is less likely to change over time, enabling higher quality stability (functional stability) of the sensor.

In the magnetic sensor, a magnetic gap may be provided in the magnetic permeability section. In some cases, the magnetically permeable section may have a magnetic shielding function for preventing an external magnetic field from being applied to the magnetoresistance effect element. In such a case, the magnetic gap can increase the magnetic resistance of the magnetically permeable section, enabling the magnetoresistance effect element to receive the external magnetic field.

When the magnetic gap is provided, the magnetic gap may be provided on a second surface facing the first surface among the surfaces of the wiring line in a direction orthogonal to the first direction. When the external magnetic field is collected in the magnetically permeable section, the magnetic resistance on the second surface side increases, enabling the external magnetic field to be efficiently guided to the first surface side (the side the magnetoresistance effect element is disposed).

In the magnetic sensor, the magnetically permeable section may be disposed on at least one of side surfaces facing in the first direction among the surfaces of the wiring line. The magnetically permeable section disposed on a side surface can function as a magnetic collector that collects the induced magnetic field from the wiring line, and also function as a magnetic collector that collects the external magnetic field in the first direction. In particular, when the length of the magnetically permeable section in the first direction becomes greater, the external magnetic field in the first direction can be efficiently collected by the magnetically permeable section. Accordingly, compared to the case in which the magnetically permeable section is not provided, the greater external magnetic field can be applied to the magnetoresistance effect element.

When the magnetically permeable section is disposed on at least part of the side surface, when the magnetically permeable section does not extend on the second surface, the region on the second surface function as a magnetic gap, enabling the external magnetic field to be efficiently collected to the first surface side on which the magnetoresistance effect element is disposed.

When the magnetically permeable section is disposed at least part of the side surface, an end portion facing the magnetoresistance effect element among end portions of the magnetically permeable section on the second direction side may convert a component of an applied external magnetic field in the second direction into a component in the first direction to apply the component to the magnetoresistance effect element. In such a case, the magnetic sensor has a function of detecting an external magnetic field in the second direction.

In the magnetic sensor, the wiring line and the magnetoresistance effect element may be formed on the same substrate. When the wiring line and the magnetoresistance effect element are formed on the same substrate, the wiring line has dimensions equivalent to the dimensions of the magnetoresistance effect element, and in such a case, it is not easy to increase the amount of current flowing through the wiring line. Even in such a case, the use of a structure like that of the magnetic sensor to increase the induced magnetic field from the wiring line enables efficient noise reduction and other functions to be achieved.

In this case, the first direction may be one of in-plane directions of the substrate, and the second direction may be a thickness direction of the substrate. This structure is advantageous in manufacturing.

### BRIEF DESCRIPTION OF THE DRAWINGS

FIG. 1 is a circuit diagram illustrating a magnetic sensor according to an embodiment of the invention;

FIG. 2 is a cross-sectional view taken along line II-II in FIG. 1;

FIG. 3 is a graph illustrating the relationship between the efficiency of the bias magnetic field and the width of the magnetically permeable section as a result of a first example;

FIG. 4 is a graph illustrating the relationship between the amplification factor of the external magnetic field and the width of the magnetically permeable section as a result of a first example;

FIG. 5 is a cross-sectional view illustrating a structure of a magnetic sensor according to an example 2-1;

FIG. 6 is a cross-sectional view illustrating a structure of a magnetic sensor according to an example 2-2;

FIG. 7 is a cross-sectional view illustrating a structure of a magnetic sensor according to an example 2-3;

FIG. 8A is a cross-sectional view illustrating a structure of a magnetic sensor according to an example 2-6;

FIG. 8B is a cross-sectional view illustrating a modification of the magnetic sensor according to the example 2-6;

FIG. 9 is a circuit diagram illustrating a magnetic sensor according to an example 2-7;

FIG. 10A is a cross-sectional view taken along line XA-XA in FIG. 9;

FIG. 10B is a cross-sectional view illustrating a modification of the magnetic sensor according to the example 2-7;

FIG. 11 is a cross-sectional view illustrating a structure of a magnetic sensor according to a modification of one embodiment of the invention;

FIG. 12 is a cross-sectional view illustrating a structure of a magnetic sensor according to another modification of one embodiment of the invention; and

FIG. 13 is a cross-sectional view illustrating a structures of a magnetic sensor according to still another modification of one embodiment of the invention.

### DESCRIPTION OF THE PREFERRED EMBODIMENTS

Hereinafter, embodiments of the present invention will be described with reference to the drawings. In the following descriptions, the same reference numerals are given to the same components and descriptions of the components described once will be omitted as appropriate.

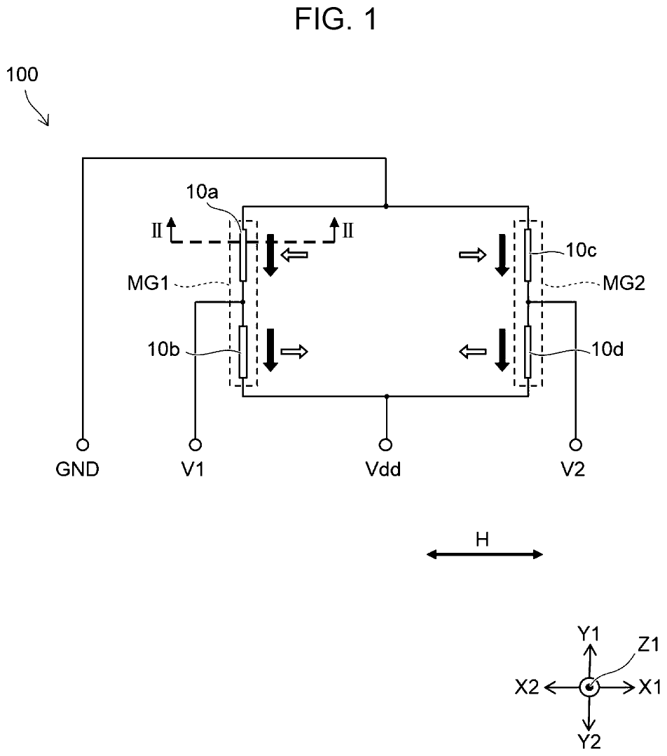

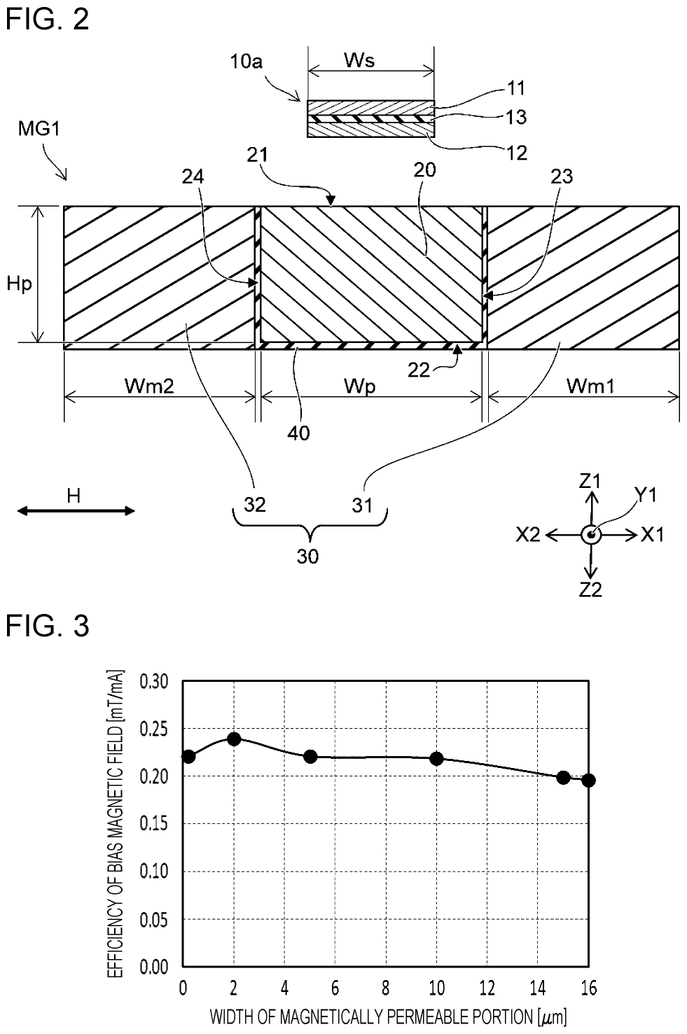

FIG. 1 is a circuit diagram illustrating a magnetic sensor according to an embodiment of the invention. FIG. 2 is a cross-sectional view taken along line A-A′ in FIG. 1. As illustrated in FIG. 1, a magnetic sensor 100 according to an embodiment of the invention includes magnetoresistance effect elements 10a, 10b, 10c, and 10d (when these elements are not distinguished, they are referred to as magnetoresistance effect elements 10 as appropriate). The four magnetoresistance effect elements 10 may be provided on the same substrate (one chip). In this embodiment, the four magnetoresistance effect elements 10 are provided on the same substrate (not illustrated). FIG. 1 is a diagram illustrating the magnetic sensor 100 viewed from a stacked surface (front surface) of the substrate in the direction of the normal to the substrate. More specifically, in FIG. 1, the Z1 side in the Z1-Z2 direction denotes the front side of the substrate, and the Z2 side in the Z1-Z2 direction denotes the rear side of the substrate. It should be noted that the Z1-Z2 direction is parallel to the stacking direction of the magnetoresistance effect element 10.

The magnetic sensor 100 includes, between a power supply terminal Vdd, which is a power supply feeding point, and a ground terminal GND, a first half-bridge circuit that has a magnetoresistance effect element 10a and a magnetoresistance effect element 10b both extending in the Y direction and connected in series, and a second half-bridge circuit that has a magnetoresistance effect element 10c and a magnetoresistance effect element 10d both extending in the Y direction and connected in series, which are connected in parallel.

The first half-bridge circuit includes an output terminal V1 between the magnetoresistance effect element 10a and the magnetoresistance effect element 10b. The second half-bridge circuit includes an output terminal V2 between the magnetoresistance effect element 10c and the magnetoresistance effect element 10d. Based on a potential difference (Va−Vb, midpoint potential difference) of outputs of these two output terminals V1 and V2, the magnitude of an external magnetic field that is externally applied as a detection magnetic field H can be quantitatively measured.

The pair of the magnetoresistance effect elements 10a and 10b of the first half-bridge circuit include pinned magnetic layers 11 that have magnetization directions in the X2 direction in the X1-X2 directions and in the X1 direction in the X1-X2 directions respectively, as indicated by the white arrow in FIG. 1. The pair of the magnetoresistance effect elements 10c and 10d of the second half-bridge circuit include pinned magnetic layers 11 that have magnetization directions in the X1 direction of the X1-X2 directions and in the X2 direction in the X1-X2 directions respectively, as indicated by the white arrow in FIG. 1.

In the first half-bridge circuit and the second half-bridge circuit, the magnetization directions of the pinned magnetic layers 11 in the magnetoresistance effect elements 10a and 10c on the power supply terminal Vdd side are opposite (anti-parallel). The magnetization directions of the pinned magnetic layers 11 in the magnetoresistance effect elements 10b and 10d on the ground terminal GND side are opposite (anti-parallel). Accordingly, sensitivity axis directions of the magnetoresistance effect elements 10 are the X1-X2 directions, and in this specification, the sensitivity axis directions are also referred to as “first direction”.

The magnetization directions (bias magnetic field directions) of free magnetic layers 12 in the four magnetoresistance effect elements 10a to the magnetoresistance effect element 10d are the same in a state in which no external magnetic field is applied, and the magnetization directions are parallel to the Y2 direction in the Y1-Y2 directions, as indicated by the black arrows in FIG. 1.

With the above-described configuration, as the magnitude of a detection magnetic field H in the X1-X2 direction changes, the output of the output terminal V1 from the first half-bridge circuit and the output of the output terminal V2 from the second half-bridge circuit change in opposite directions. As a result, a large output can be obtained as a potential difference between the two output terminals V1 and V2. Accordingly, the magnetic sensor 100 can detect the detection magnetic field H with high accuracy. It should be noted that, instead of the full-bridge circuit, the first or second half-bridge circuit or the magnetoresistance effect element 10 may be used.

As illustrated in FIG. 2, the magnetoresistance effect element 10a may be, for example, a giant magnetoresistance effect (GMR) element or a tunneling magnetoresistance effect (TMR) element. The magnetoresistance effect element 10a includes the pinned magnetic layer 11, the free magnetic layer 12, and an intermediate layer 13 that is formed between the pinned magnetic layer 11 and the free magnetic layer 12. The resistance value of the magnetoresistance effect element 10a changes depending on the relative relationship between the magnetization direction of the pinned magnetic layer 11, whose magnetization direction is fixed, and the free magnetic layer 12, whose magnetization direction changes depending on an external magnetic field. The magnetic sensor 100 can measure the direction and strength of an external magnetic field to be measured based on a change in the resistance value of the magnetoresistance effect element 10a.

When the magnetoresistance effect element 10a is a GMR element, the pinned magnetic layer 11 comprises a ferromagnetic layer composed of, for example, a cobalt-iron alloy (CoFe alloy). The free magnetic layer 12 comprises a soft magnetic material composed of, for example, a CoFe alloy or a nickel-iron alloy (NiFe alloy), and has a single-layer structure, a multilayer structure, a multilayer ferrimagnetic structure, or the like. The intermediate layer 13 comprises a non-magnetic intermediate layer composed of, for example, Cu.

To stabilize the output of the magnetic sensor 100, a bias magnetic field is applied to the free magnetic layer 12 in a direction orthogonal to the sensitivity axis direction (the first direction). The magnetic sensor 100 according to the embodiment has the bias magnetic field direction in the Y2 direction in the Y1-Y2 directions as illustrated in FIG. 1. This bias magnetic field enables the soft magnetic material in the free magnetic layer 12 to have an aligned magnetization direction when no magnetic field is applied.

As described above, the magnetization direction of the pinned magnetic layer 11 of the magnetoresistance effect element 10a is fixed in the X2 direction in the X1-X2 directions, and when no magnetic field is applied, the magnetization direction of the free magnetic layer 12 is in the Y2 direction in the Y1-Y2 directions, which is orthogonal to the magnetization direction of the pinned magnetic layer 11. Accordingly, the resistance values of the magnetoresistance effect element 10a change in the opposite directions depending on whether the direction of the detection magnetic field H is the X1 direction or the X2 direction in the X1-X2 direction directions. More specifically, the resistance values exhibit odd function characteristics with respect to the detection magnetic field H in the X1-X2 direction, and thus the directions and magnitudes of the detection magnetic field H can be continuously measured.

A TMR element may be used as the magnetoresistance effect element 10a instead of the above-described GMR element. In such a case, the intermediate layer 13 serves as an insulating barrier layer that comprises a material such as MgO, Al₂O₃, titanium oxide, or other similar materials.

The magnetoresistance effect element 10b to the magnetoresistance effect element 10d have a basic structure in common with the magnetoresistance effect element 10a. From the viewpoint of increasing the measurement accuracy, it is preferable that the magnetoresistance effect element 10a to the magnetoresistance effect element 10d be manufactured on the same substrate in a common manufacturing process.

As illustrated in FIG. 1, on the Z2 side of the magnetoresistance effect elements 10a and 10b in the Z1-Z2 direction, a magnetic field generating section MG1 is disposed, and on the Z2 side of the magnetoresistance effect elements 10c and 10d in the Z1-Z2 direction, a magnetic field generating section MG2 is disposed. In the magnetic sensor 100, the magnetic field generating section MG1 and the magnetic field generating section MG2 have the same structure.

As illustrated in FIG. 2, the magnetic field generating section MG1 is disposed on the Z2 side of the magnetoresistance effect element 10a in the Z1-Z2 direction and has a wiring line 20 that extends in the Y1-Y2 direction. More specifically, the wiring line 20 is disposed on the Z2 side of the magnetoresistance effect element 10a in the Z1-Z2 direction, which is a second direction intersecting the first direction (X1-X2 direction), and has a first surface 21 that faces toward the Z1 side in the Z1-Z2 direction to face the magnetoresistance effect element 10a.

The wiring line 20 in the magnetic sensor 100 according to the embodiment is formed so as to be embedded in the substrate (not illustrated) together with the magnetoresistance effect element 10a. The material of the wiring line 20 is not particularly limited as long as it is a conductive element, and is preferably a material based on a non-magnetic element such as copper or aluminum. It should be noted that it may be advantageous in manufacturing that the first direction is one of in-plane directions of the substrate and the second direction is the thickness direction of the substrate. The distance between the wiring line 20 and the magnetoresistance effect element 10a is set such that a predetermined induced magnetic field from the wiring line 20 is applied to the magnetoresistance effect element 10a. In this embodiment, the magnetoresistance effect element 10a is formed by a film forming process on the substrate in which the wiring line 20 is embedded. As an example, the distance is set to the micron order or the submicron order.

By energizing the wiring line 20, an induced magnetic field in the sensitivity axis direction (the first direction, the X1-X2 direction) is applied to the free magnetic layer 12 in the magnetoresistance effect element 10a as a bias magnetic field. In the magnetic sensor 100 according to the embodiment, the width (length in the X1-X2 direction) and the height (length in the Z1-Z2 direction) of the wiring line 20 are approximately several m and the wiring line 20 is embedded in the substrate as described above, and this structure limits the amount of current that can flow through the wiring line 20 due to the heat dissipation efficiency of Joule heat. Accordingly, there is a limit to strengthening the induced magnetic field applied to the free magnetic layer 12 by increasing the amount of current flowing through the wiring line 20. When a magnetic field having a strength equivalent to the saturation magnetic field of the magnetoresistance effect element 10a is applied as a bias magnetic field, in particular, the problem that the amount of current flowing through the wiring line 20 has a substantial upper limit is likely to become apparent.

Accordingly, the magnetic field generating section MG1 in the magnetic sensor 100 includes a magnetically permeable section 30 that comprises a ferromagnetic material and is disposed at least part of a surface other than the first surface 21 among the surfaces of the wiring line 20. In the magnetic sensor 100 according to the embodiment, a cross-sectional shape of the wiring line 20 in the XY plane is rectangular, and the surfaces of the wiring line 20 other than the first surface 21 include a second surface 22, which faces the first surface 21 in the second direction, and two surfaces (a third surface 23 and a fourth surface 24), which face in the first direction (the X1-X2 direction). As illustrated in FIG. 2, among these surfaces, the magnetically permeable section 30 comprises a first magnetically permeable portion 31, which is disposed on the third surface 23, and a second magnetically permeable portion 32, which is disposed on the fourth surface 24.

The magnetically permeable section 30 (the first magnetically permeable portion 31 and the second magnetically permeable portion 32) can collect an induced magnetic field from the wiring line 20 and efficiently apply a bias magnetic field in the first direction (X1-X2 direction) to the free magnetic layer 12 in the magnetoresistance effect element 10a. In particular, even when a bias magnetic field that has a strength equivalent to a saturation magnetic field of the magnetoresistance effect element 10a is required, the magnetic sensor 100 according to the embodiment can apply a magnetic field having an appropriate strength by using the induced magnetic field of the wiring line 20.

The material of the magnetically permeable section 30 is not particularly limited as long as it is a ferromagnetic material. As a specific example, a soft magnetic material such as permalloy may be used. The distance between the magnetically permeable section 30 and the wiring line 20 is not limited. For example, the distance may be several m in dimension, which is equivalent to the dimensions (height, width) of the wiring line 20.

The length (first-direction length) of the magnetically permeable section 30 (the first magnetically permeable portion 31 and the second magnetically permeable portion 32) in the first direction (X1-X2 direction) is appropriately set depending on the strength of the bias magnetic field to be applied to the free magnetic layer 12. When the first-direction length is excessively short, the magnetically permeable section 30 may fail to appropriately perform the function of collecting the induced magnetic field. In addition, when the first-direction length is excessively long, the induced magnetic field is dispersed in the magnetically permeable section 30 and it may be difficult to increase the strength of the induced magnetic field applied to the free magnetic layer 12 as a bias magnetic field in the first direction. On the other hand, in some cases, the magnetically permeable section 30 that is long in the first-direction can effectively function as a magnetic collector for an external magnetic field in the first direction. Accordingly, it is preferable that the first-direction length be set in view of the ratio between the strength of the induced magnetic field applied to the free magnetic layer 12 and the strength of the external magnetic field.

The magnetic field generating section MG1 in the magnetic sensor 100 according to the embodiment includes an insulating layer 40 between the wiring line 20 and the magnetically permeable section 30. When the magnetically permeable section 30 is composed of a metal material such as permalloy, the resistivity of the magnetically permeable section 30 is relatively low, and when the insulating layer 40 is not provided, the electric current also flows through the magnetically permeable section 30 when energized. As a result, the amount of current flowing through the wiring line 20 decreases relatively and the strength of the induced magnetic field from the wiring line 20 also decreases.

The insulating layer 40 may be composed of any material and have any thickness as long as the insulating layer 40 can prevent the current flowing through the wiring line 20 from flowing into the magnetically permeable section 30. The insulating layer 40 is preferably a diffusion suppression layer that suppresses interdiffusion between an element forming the wiring line 20 and an element forming the magnetically permeable section 30. When the insulating layer 40 suppresses interdiffusion between the wiring line 20 and the magnetically permeable section 30, the composition of the wiring line 20 and the magnetically permeable section 30 less likely to change over time, enabling higher quality stability (functional stability) of the magnetic sensor 100. From the viewpoint of the diffusion suppression layer, specific examples of materials of the insulating layer 40 include oxide-based materials such as silica (SiO₂) and alumina (Al₂O₃), and nitride-based materials such as silicon nitride (Si₃N₄) and aluminum nitride (AlN), and in some cases, the thickness may preferably be 50 nm or greater.

It should be noted that the above-described embodiment is provided to facilitate understanding of the present invention and does not limit the invention. Accordingly, the components disclosed in the embodiment are intended to include all design changes and equivalents that fall within the technical scope of the present invention.

### EXAMPLES

Hereinafter, the present invention will be described in more detail using examples based on simulations; however, the present invention is not limited to these examples. Magnetic sensors according to the examples had circuit configurations similar to the circuit configuration (full-bridge circuit) of the magnetic sensor 100 according to the above-described embodiment, and included the four magnetoresistance effect elements 10a to the magnetoresistance effect element 10d. The differences in the examples were the structures of the magnetic field generating sections MG1 and the magnetic field generating sections MG2. Accordingly, in the following examples (except the example 2-7), the structures will be described with reference to cross-sectional views similar to the cross-sectional view of the magnetic sensor 100 taken along line II-II.

### Example 1

The magnetic sensor 100 according to the first example had the cross-sectional structure illustrated in FIG. 2. More specifically, the magnetic field generating section MG1 was disposed on the Z2 side of the magnetoresistance effect element 10a in the Z1-Z2 direction and had the wiring line 20 that extended in the Y1-Y2 direction. Among the surfaces of the wiring line 20, the first magnetically permeable portion 31 and the second magnetically permeable portion 32 were disposed on the third surface 23 and the fourth surface 24, which faced in the first direction (X1-X2 direction), respectively and the magnetically permeable section 30 was not provided on the first surface 21, which faced the magnetoresistance effect element 10a, and the second surface 22, which faced the first surface 21. The insulating layer 40 was disposed between the first magnetically permeable portion 31 and the second magnetically permeable portion 32 and the wiring line 20.

In the first embodiment, the length (element width Ws) of the magnetoresistance effect element 10a in the X1-X2 direction was 1.0 μm, and the length (element length) in the Y1-Y2 direction was 64 μm. The length (wiring line width Wp) of the wiring line 20 in the X1-X2 direction was 2.0 μm, the length (wiring line height Hp) in the Z1-Z2 direction was 1.5 μm, and the length (wiring line length) in the Y1-Y2 direction was 80 μm. The distance between the magnetoresistance effect element 10a and the wiring line 20 was 0.25 μm, and the thickness of the insulating layer 40 was 0.5 μm.

The lengths (magnetically permeable portion lengths) of the first magnetically permeable portion 31 and the second magnetically permeable portion 32 in the Y1-Y2 direction were 80 μm, which were equal to the wiring line length, and the length (first magnetically permeable portion length Wm1) of the first magnetically permeable portion 31 in the X1-X2 direction and the length (second magnetically permeable portion length Wm2) of the second magnetically permeable portion 32 in the X1-X2 direction were equal and were changed in the range of 0.2 μm to 16 μm. Hereinafter, these widths of the magnetically permeable portions are briefly referred to as “magnetically permeable portion widths”.

The current flowing through the wiring line 20 was 1 μmA, and the strength of an external magnetic field applied in the first direction (X1-X2 direction) was 1 mT.

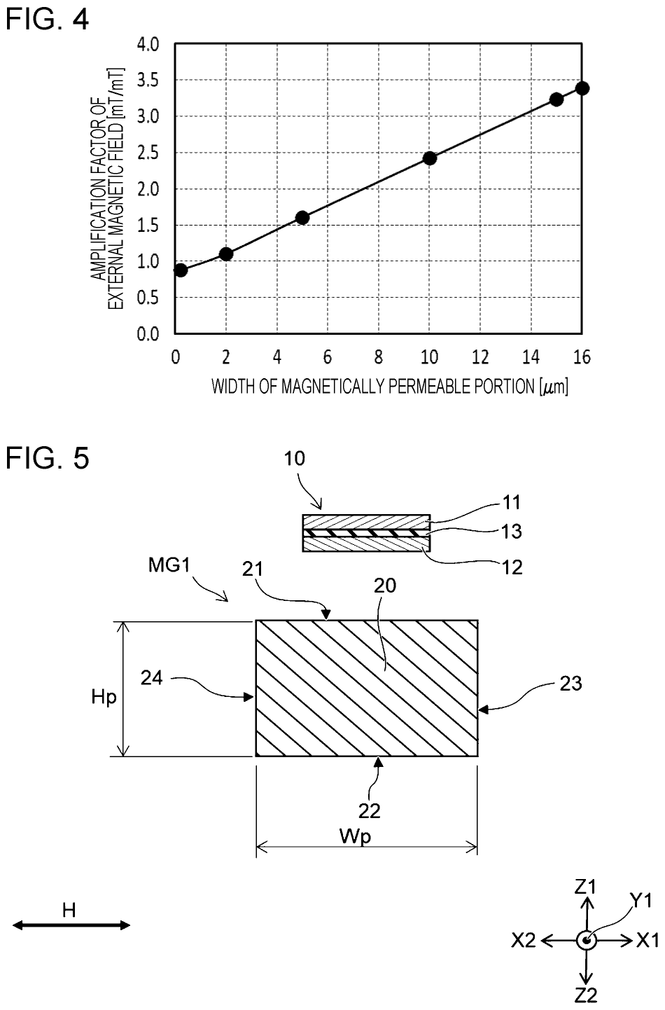

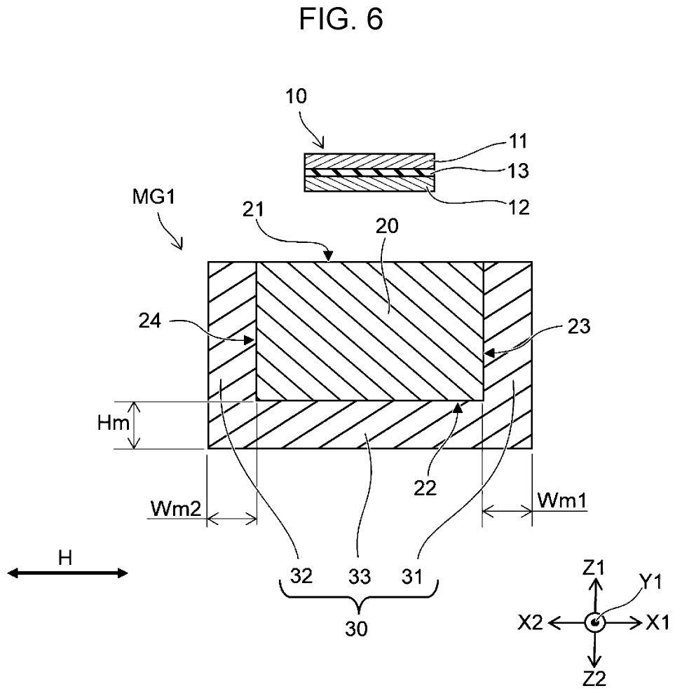

Under the above conditions, the efficiency of the bias magnetic field applied to the magnetoresistance effect element 10a as a saturation magnetic field (bias magnetic field induced by the induced magnetic field/current value, unit: mT/mA) and the amplification factor of the external magnetic field (detection magnetic field H/applied external magnetic field, unit: mT/mT) were simulated. The results are illustrated in Table 1, FIG. 3, and FIG. 4.

TABLE 1

| | Wm1, | Efficiency of | Amplification Factor | |
|---|---|---|---|---|
| Test | Wm2 | Bias Magnetic | of External Magnetic | |
| Number | [μm] | Field [mT/mA] | Field [mT/mT] | Remarks |
| 1-1 | 0.2 | 0.221 | 0.88 | Example in |
| | | | | Present |
| | | | | Invention |
| 1-2 | 2 | 0.239 | 1.11 | Example in |
| | | | | Present |
| | | | | Invention |
| 1-3 | 5 | 0.221 | 1.61 | Example in |
| | | | | Present |
| | | | | Invention |
| 1-4 | 10 | 0.218 | 2.42 | Example in |
| | | | | Present |
| | | | | Invention |
| 1-5 | 15 | 0.199 | 3.23 | Example in |
| | | | | Present |
| | | | | Invention |
| 1-6 | 16 | 0.196 | 3.39 | Example in |
| | | | | Present |
| | | | | Invention |

As illustrated in FIG. 3, the relationship between the efficiency of the bias magnetic field and the magnetically permeable portion widths (the first magnetically permeable portion width Wm1 and the second magnetically permeable portion width Wm2) had a maximum value at a magnetically permeable portion width of approximately 2 μm. Up to a magnetically permeable portion width of approximately 2 μm, by providing the magnetically permeable section 30, the induced magnetic field from the wiring line 20 was efficiently collected by the magnetically permeable section 30 and the collected magnetic field was applied to the magnetoresistance effect element 10a, and thereby the efficiency of the bias magnetic field was increased. On the other hand, when the magnetically permeable portion width became approximately 2 μm or greater, the efficiency of the bias magnetic field decreased, and when the magnetically permeable portion width was 15 μm or greater, the efficiency became equivalent to a case in which the magnetically permeable section 30 was not provided (embodiment 2-1 described below). When the magnetically permeable portion width became excessively large, the induced magnetic field was probably dispersed in the magnetically permeable section 30, and the magnetic collecting function of the magnetically permeable section 30 seems to be reduced.

On the other hand, the relationship between the amplification factor of the external magnetic field and the magnetically permeable portion width was approximately linear as illustrated in FIG. 4. That is, it was confirmed that the magnetically permeable section 30 (the first magnetically permeable portion 31 and the second magnetically permeable portion 32) according to the example 1 had the function of collecting the external magnetic field in the first direction and applying the collected external magnetic field to the magnetoresistance effect element 10a, and this function became stronger as the magnetically permeable portion width became greater. In addition, in the graph illustrated in FIG. 4, the amplification factor was 1 when the magnetically permeable portion width was 1 μm. Accordingly, in the magnetically permeable section 30 (the first magnetically permeable portion 31 and the second magnetically permeable portion 32) according to the embodiment 1, the shielding function of blocking the application of the external magnetic field in the first direction to the magnetoresistance effect element 10a did not become apparent when the magnetically permeable portion width was 1 μm or greater.

### Example 2

In the example 1, the effect of the width of the magnetically permeable portion on the efficiency of the bias magnetic field and the amplification factor of the external magnetic field was evaluated. In these examples, the effects in cases in which the shape of the magnetically permeable section 30 was further changed were evaluated. Simulations were performed for a plurality of magnetic field generating sections MG1 having different shapes of magnetically permeable sections 30.

### Example 2-1

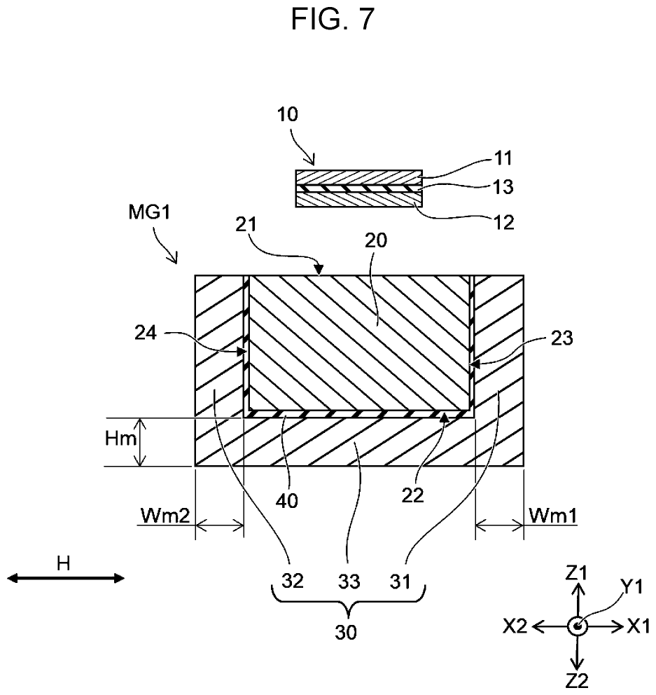

In the magnetic field generating section MG1 according to the example 2-1, as illustrated in FIG. 5, both the first magnetically permeable portion width Wm1 and the second magnetically permeable portion width Wm2 were 0 μm, and the insulating layer 40 was not provided. The shape of the wiring line 20 was the same as that in the first embodiment (wiring line width Wp: 2.0 μm, wiring line height Hp: 1.5 μm, and wiring line length: 64 μm), and the distance between the magnetoresistance effect element 10a and the wiring line 20 was also the same as that in the first embodiment (0.25 μm). The direction of application of the external magnetic field was the first direction (X1-X2 direction).

### Example 2-2

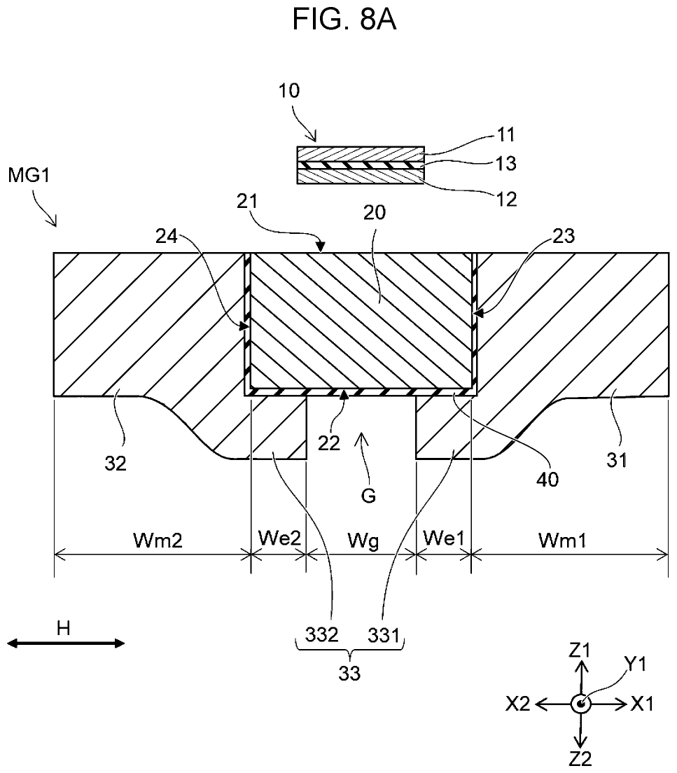

In the magnetic field generating section MG1 according to the example 2-2, as illustrated in FIG. 6, the magnetically permeable section 30 that had a thickness of 0.5 μm was provided on the second surface 22, the third surface 23, and the fourth surface 24 of the wiring line 20, which had the same shapes as those in the first embodiment. More specifically, the magnetically permeable section 30 in the magnetic field generating section MG1 according to the example 2-2 had the first magnetically permeable portion 31, which had a first magnetically permeable portion width Wm1 of 0.5 μm, the second magnetically permeable portion 32, which had a second magnetically permeable portion width Wm2 of 0.5 μm, and a third magnetically permeable portion 33, which had a magnetically permeable section height Hm of 0.5 μm. The magnetically permeable section 30 had a U-shaped cross-sectional shape as a whole. The direction of application of the external magnetic field was the first direction (X1-X2 direction).

### Example 2-3

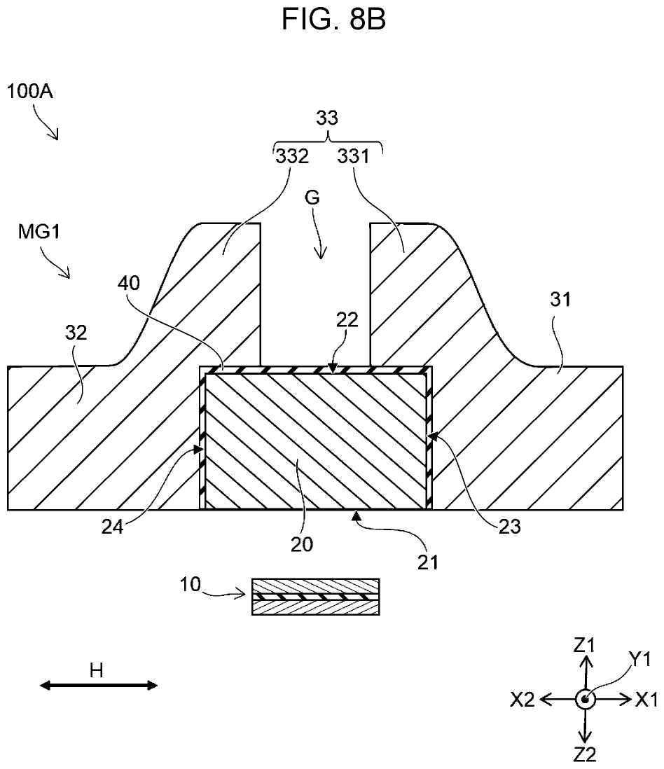

The magnetic field generating section MG1 according to the example 2-3 had, as illustrated in FIG. 7, a structure similar to that in the example 2-2, and had the insulating layer 40 that had a thickness of 0.1 μm between the wiring line 20 and the magnetically permeable section 30. The direction of application of the external magnetic field was the first direction (X1-X2 direction).

### Example 2-4

The magnetic field generating section MG1 according to the example 2-4 had the structure illustrated in FIG. 2, and both the width of the first magnetically permeable portion 31 (first magnetically permeable portion width Wm1) and the width of the second magnetically permeable portion 32 (second magnetically permeable portion width Wm2) were 0.5 μm. The direction of application of the external magnetic field was the first direction (X1-X2 direction).

### Example 2-5

The magnetic field generating section MG1 according to the example 2-5 had the structure illustrated in FIG. 2, and both the width of the first magnetically permeable portion 31 (first magnetically permeable portion width Wm1) and the width of the second magnetically permeable portion 32 (second magnetically permeable portion width Wm2) were 16 μm. The direction of application of the external magnetic field was the first direction (X1-X2 direction).

### Example 2-6

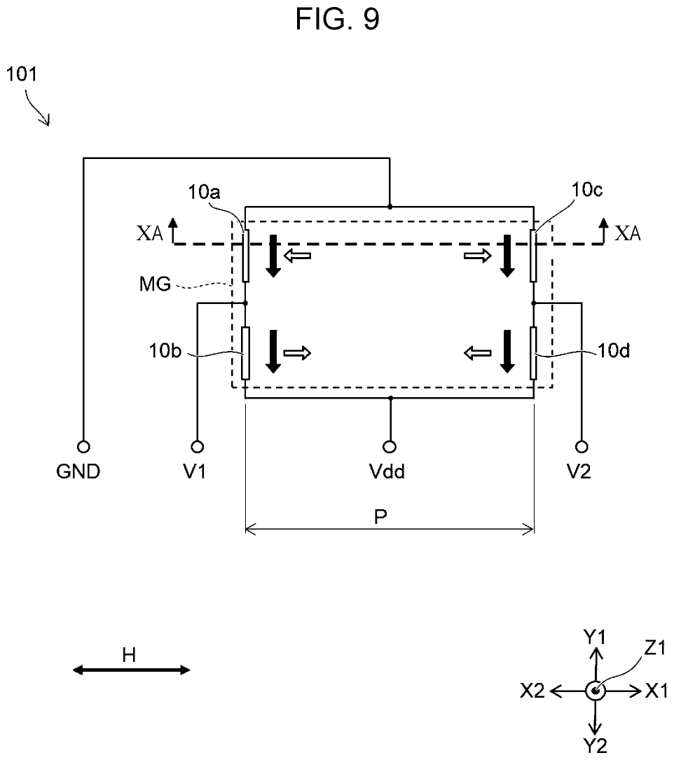

In the magnetic field generating section MG1 according to the example 2-6, as illustrated in FIG. 8A, on the third surface 23 and the fourth surface 24 of the wiring line 20, which had the same shapes as those in the first embodiment, the first magnetically permeable portion 31 that had a first magnetically permeable portion width Wm1 of 16 μm was provided on the third surface 23, and the second magnetically permeable portion 32 that had a second magnetically permeable portion width Wm2 of 16 μm was provided on the fourth surface 24, similarly to the example 2-5. In the example 2-6, the first magnetically permeable portion 31 had a first extending portion 331 that extended on the second surface 22 of the wiring line 20, and the extension width We1 was 0.6 μm. The second magnetically permeable portion 32 also had a second extension portion 332 that extended on the second surface 22 of the wiring line 20, and the extension width We2 was 0.6 μm. In other words, the magnetic field generating section MG1 according to the example 2-6 had a third magnetically permeable section 33 that had a magnetic gap G having a width (gap width Wg) of 1.0 μm on the second surface 22 of the wiring line 20. The direction of application of the external magnetic field was the first direction (X1-X2 direction).

### Example 2-7

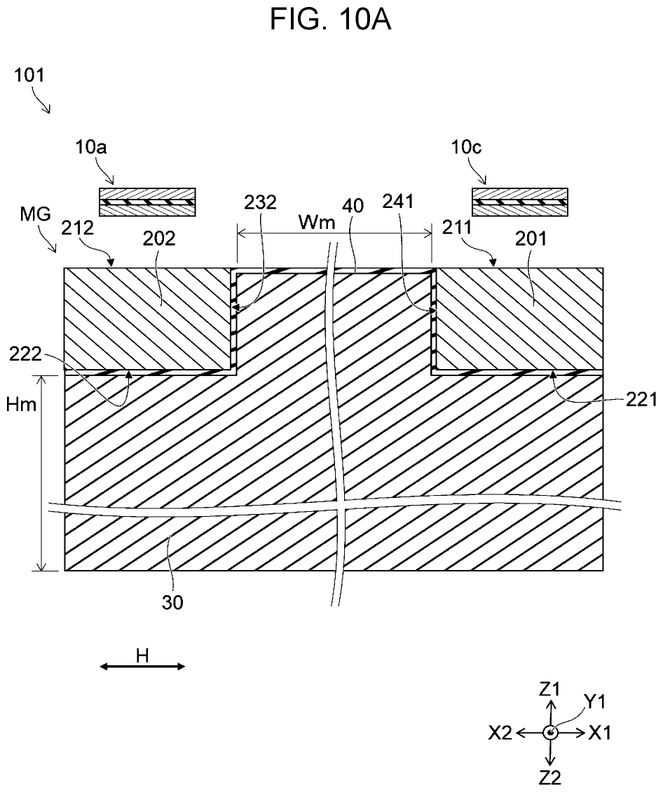

A magnetic sensor 101 according to the example 2-7 was for measuring an external magnetic field in the second direction (Z1-Z2 direction), different from the magnetic sensors 100 according to the other examples. As illustrated in FIG. 9, the circuit configuration was similar to that in the magnetic sensor 100 illustrated in FIG. 1, and the direction (sensitivity axis direction) of the four magnetoresistance effect elements 10a to 10d for the detection magnetic field H was parallel to the first direction (X1-X2 direction). A magnetic field generating section MG was disposed on the Z2 side of the four magnetoresistance effect elements 10a to the magnetoresistance effect element 10d in the second direction (Z1-Z2 direction). An array pitch P between the magnetoresistance effect element 10a and the magnetoresistance effect element 10c that were disposed adjacent to each other in the first direction (X1-X2 direction) was 12.2 μm.

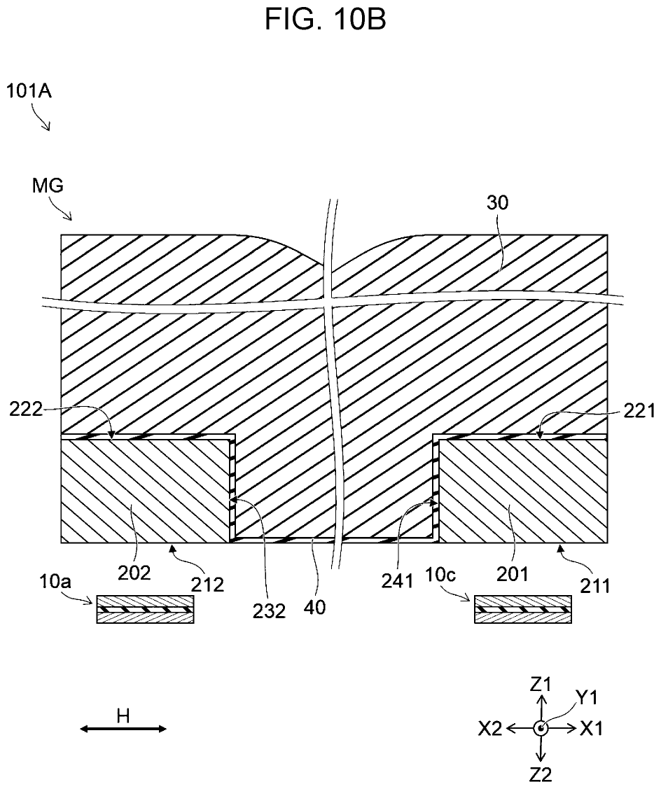

FIG. 10A is a cross-sectional view taken along line XA-XA in FIG. 9. As illustrated in FIG. 10A, on the Z2 side of the magnetoresistance effect elements 10a in the second direction (Z1-Z2 direction), a wiring line 202 that had a first surface 212 that faced the magnetoresistance effect element 10a was disposed, and on the Z2 side of the magnetoresistance effect elements 10c in the second direction (Z1-Z2 direction), a wiring line 201 that had a first surface 211 that faced the magnetoresistance effect element 10c was disposed.

The insulating layer 40 was disposed on a second surface 221 and a fourth surface 241 of the wiring line 201 and on a second surface 222 and a third surface 232 of the wiring line 202, and these insulating layers 40 were continuous. Between the wiring line 201 and the wiring line 202 in the first direction (X1-X2 direction), the magnetically permeable section 30 was disposed to fill the space, and the magnetic permeability section width Wm was 10 μm. The magnetically permeable section 30 was also disposed on the Z2 side of each of the wiring line 201 and the wiring line 202 in the second direction (Z1-Z2 direction), and the length (magnetically permeable section height Hm) from the second surfaces 221 and 222 in the second direction (Z1-Z2 direction) was 10 μm.

A simulation similar to that in the first embodiment was performed for each example to obtain the efficiency of the bias magnetic field and the amplification factor of the external magnetic field. Table 2 illustrates the results.

TABLE 2

| | | Amplification | |
|---|---|---|---|
| | Efficiency of | Factor of | |
| | Bias Magnetic | External | |
| Exam- | Field | Magnetic Field | |
| ple | [mT/mA] | [mT/mT] | Remarks |
| 2-1 | 0.16 | 1 | Comparative Example |
| 2-2 | 0.45 | 0.22 | Example in Present Invention |
| 2-3 | 0.45 | 0.22 | Example in Present Invention |
| 2-4 | 0.22 | 0.88 | Example in Present Invention |
| 2-5 | 0.20 | 3.39 | Example in Present Invention |
| 2-6 | 0.27 | 2.28 | Example in Present Invention |
| 2-7 | 0.28 | 0.82 | Example in Present Invention |

As illustrated in Table 2, when the magnetically permeable section 30 was disposed to cover the surfaces other than the first surface 21 (example 2-2), the bias magnetic field increased significantly (2.8 times) compared to the case (example 2-1) in which the magnetically permeable section 30 was not provided, but the detection magnetic field H attenuated (0.22 times). In the example (example 2-3) in which the insulating layer 40 was disposed between the magnetically permeable section 30 and the wiring line 20, the same result as that in the example 2-2 was obtained.

In the magnetic field generating sections MG1 according to the example 2-2 and the example 2-3, since the magnetically permeable sections 30 were disposed to cover the second surfaces 22, the third surfaces 23, and the fourth surfaces 24, the induced magnetic fields of the wiring lines 20 seemed to be efficiently collected by the magnetically permeable section 30 and applied to the magnetoresistance effect element 10a. On the other hand, in each of the magnetic field generating sections MG1 according to these examples, since the magnetically permeable section 30 having the U-shaped cross section was disposed, the external magnetic field in the first direction (X1-X2 direction) was collected on one side (for example, the first magnetically permeable portion 31) of the sides of the magnetically permeable section 30, and the collected magnetic flux flowed through the third magnetically permeable section 33 to the other side (the second magnetically permeable portion 32). As a result, the strength of the detection magnetic field H detected in the magnetoresistance effect element 10a seemed to be decreased. In other words, the results in the magnetic field generating sections MG1 according to the example 2-2 and in the magnetic field generating section MG1 according to the example 2-3 show that the shielding functions of the external magnetic fields became apparent.

When the magnetically permeable section 30 was not provided on the second surface 22 (example 2-4), compared to the example 2-3, the bias magnetic field was attenuated (approximately ½), but the degree of attenuation of the detection magnetic field H decreased less and the result was approximately 90% of the case in which the magnetically permeable section 30 was not provided (example 2-1). The magnetic field generating section MG1 in the example 2-4 did not include the magnetically permeable section 30 on the second surface 22, that is, since the magnetic field generating section MG1 in the example 2-4 did not include the third magnetically permeable section 33 compared to the magnetic field generating section MG1 in the example 2-3, the induced magnetic field around the wiring line 20 in the Y1-Y2 direction was less likely to be collected by the magnetically permeable section 30 than by the magnetic field generating section MG1 in the example 2-3. Due to this structure, the strength of the bias magnetic field probably relatively decreased.

On the other hand, compared to the magnetic field generating section MG1 in the example 2-3, the magnetic field generating section MG1 in the example 2-4 did not include the third magnetically permeable section 33, and thus when the magnetic flux of the external magnetic field collected on one side (for example, the first magnetically permeable portion 31) of the sides of the magnetically permeable section 30 flowed toward the other side (the second magnetically permeable portion 32) of the magnetically permeable section 30, there was essentially no difference whether the magnetic flux passed through the first surface 21 side or the second surface 22 side. Accordingly, compared to the magnetic field generating section MG1 in the example 2-3 in which the third magnetically permeable section 33 was provided and it was advantageous for the magnetic flux to pass through the second surface 22 side, the magnetic flux passing through the first surface 21 side increased, and as a result, the strength of the detection magnetic field H seemed to be increased in the magnetoresistance effect element 10a.

In the magnetic field generating section MG1 according to the example 2-5, compared to the magnetic field generating section MG1 in the example 2-4, the width of the first magnetically permeable portion 31 (the first magnetically permeable portion width Wm1) and the width of the second magnetically permeable portion 32 (the second magnetically permeable portion width Wm2) were greater. In this case, it has been confirmed that the amplification factor of the external magnetic field according to the first embodiment increased, and also in the example 2-5, the amplification factor was greater than that in the example 2-4 (approximately 3.8 times).

In the magnetic field generating section MG1 according to the example 2-6, compared to the magnetic field generating section MG1 in the example 2-5, the magnetically permeable section 30 extended to the second surface 22 side (the first extending portion 331 and the second extending portion 332). These extending portions corresponded to the third magnetically permeable section 33, which had the magnetic gap G having the width Wg of 1.0 μm on the second surface 22. In the magnetic field generating section MG1 in the example 2-6, due to the magnetic gap G, the efficiency of the bias magnetic field was lower than that in the case (the example 2-3, 0.45 mT/mA) in which the magnetic gap G was not provided in the third magnetically permeable section 33, but the efficiency of the bias magnetic field was higher (0.27 mT/mA) than that in the cases (the examples 2-4 and the example 2-5, 0.22 mT/mA) in which the third magnetically permeable section 33 was not provided on the second surface 22, in other words, in the case in which the magnetic gap G having the width Wg of 2.0 μm was disposed on the second surface 22 side. On the other hand, the amplification factor of the external magnetic field was higher than that in the case (the example 2-3, 0.22 mT/mT) in which the magnetic gap G was not provided in the third magnetically permeable section 33, but the amplification factor (2.28 mT/mT) of the external field was lower than that in the cases (the examples 2-4 and the example 2-5, 3.39 mT/mT) in which the third magnetically permeable section 33 was not provided on the second surface 22.

In the magnetic field generating section MG in the example 2-7, on one (the fourth surface 241 in the wiring line 201 or the third surface 232 in the wiring line 202) of the surfaces facing in the first direction and on the second surface 221 or the second surface 222, the magnetically permeable section 30 was disposed. Accordingly, the induced magnetic fields of the wiring lines 201 and 202 were appropriately collected and the efficiency of the bias magnetic field was equivalent to the case of the example 2-6. The structure in the example 2-7 was for measuring an external magnetic field in the second direction (Z1-Z2 direction) and different from those in the other examples. More specifically, among the magnetic fluxes of an external magnetic field passing through the magnetically permeable section 30 toward the Z1 side in the Z1-Z2 direction, a component changing its direction to the first direction (X1-X2 direction) when the magnetic fluxes were released at an end portion of the magnetically permeable section 30 on the Z1 side in the second direction (Z1-Z2 direction) was detected by the magnetoresistance effect element 10a and the magnetoresistance effect element 10c having their sensitivity axes in the first direction. Accordingly, the amplification factor of the external magnetic field cannot be compared to other examples; however, the result shows that the external magnetic field in a direction orthogonal to the sensitivity axis direction (the first direction) of the magnetoresistance effect element 10a and the magnetoresistance effect element 10c was detected with a strength (approximately 80%) not significantly different from that in the case in which the magnetically permeable section 30 was not provided (example 2-1).

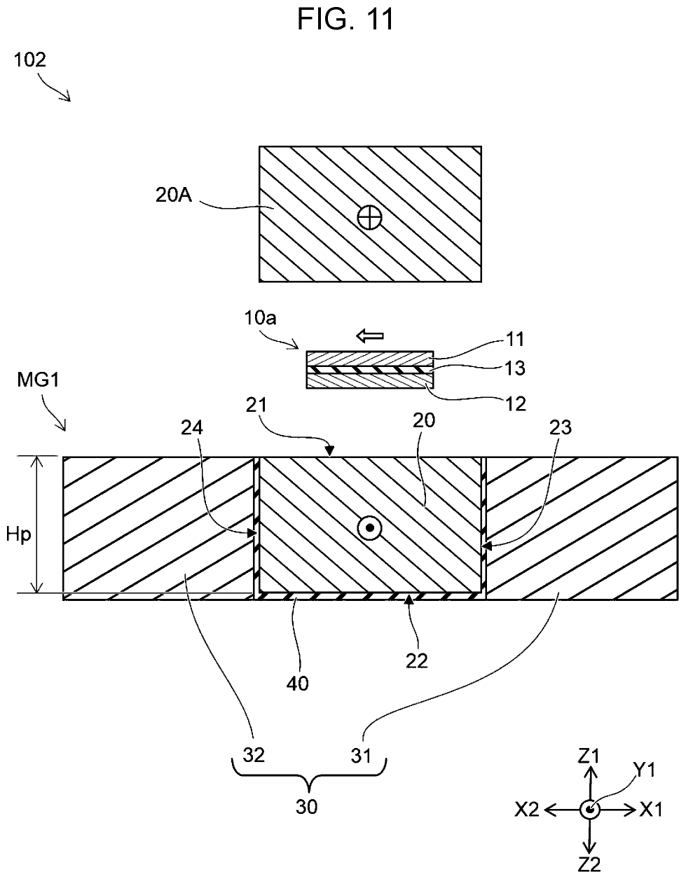

Hereinafter, modifications of the magnetic sensor according to the embodiment will be described. FIG. 11 is a modification of the magnetic sensor according to the embodiment. FIG. 11 is a cross-sectional view including cross sections of one magnetoresistance effect element 10a and the magnetic field generating section MG1 corresponding to the magnetoresistance effect element 10a, similarly to FIG. 2. As illustrated in FIG. 11, compared to the magnetic sensor 100 illustrated in FIG. 1, a magnetic sensor 102 according to the modification includes a wiring line 20A that has a shape similar to that of the wiring line 20 on the Z1 side of the magnetoresistance effect element 10a in the Z1-Z2 direction (the second direction). Electric current passes through the wiring line 20 and the wiring line 20A in opposite directions, and thereby an induced magnetic field of the same direction as of the free magnetic layer 12 in the magnetoresistance effect element 10a is applied. In FIG. 11, the current passes through the wiring line 20 to the Y1 side in the Y1-Y2 direction, and the current passes through the wiring line 20A to the Y2 side in the Y1-Y2 direction, and thereby the induced magnetic field is applied to the free magnetic layer 12 in the magnetoresistance effect element 10a in the X2 direction in the X1-X2 directions. This direction is the same as the magnetization direction of the pinned magnetic layer 11 in the magnetoresistance effect element 10a.

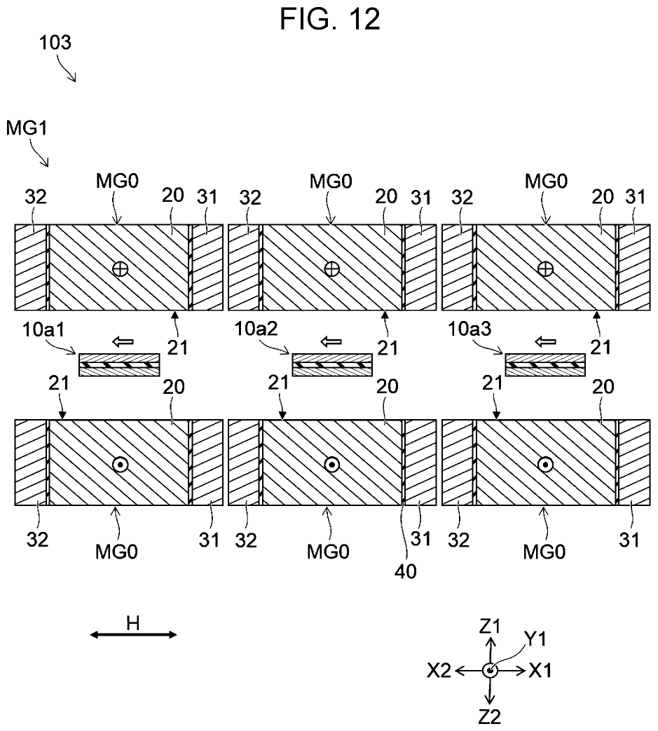

FIG. 12 illustrates another modification of the magnetic sensor according to the embodiment. FIG. 12 is a cross-sectional view including cross sections of one magnetoresistance effect element 10a and the magnetic field generating section MG1 corresponding to the magnetoresistance effect element 10a, similarly to FIG. 2. In a magnetic sensor 103 according to the modification, the magnetoresistance effect element 10a includes three magnetoresistance effect elements 10a1, 10a2, and 10a3. These magnetoresistance effect elements have the pinned magnetic layers 11 that are magnetized in the same direction (the X2 direction in the X1-X2 directions)(white arrow).

On both sides of each of the magnetoresistance effect element 10a1, the magnetoresistance effect element 10a2, and the magnetoresistance effect element 10a3 in the second direction (Z1-Z2 direction), magnetic field generating sections MG0 that have the same structure as that of the magnetic field generating section MG1 in the example 2-4 are disposed. Accordingly, in the magnetic sensor 103 according to the modification, the magnetic field generating section MG1 has six magnetic field generating sections MG0. The wiring lines 20 of the three magnetic field generating sections MG0 disposed on the Z1 side in the second direction (Z1-Z2 direction) are arranged parallel to the first direction (X1-X2 direction) to form a parallel coil, and in all of the wiring lines 20, current passes to the Y2 side in the Y1-Y2 direction. The wiring lines 20 of the three magnetic field generating sections MG0 disposed on the Z2 side in the second direction (Z1-Z2 direction) are also arranged parallel to the first direction (X1-X2 direction) to form a parallel coil, and in all of the wiring lines 20, current passes to the Y1 side in the Y1-Y2 direction. This structure enables the induced magnetic fields of the wiring lines 20 to be applied to the three magnetoresistance effect elements 10a1, 10a2, and 10a3 in the magnetization direction of the pinned magnetic layers 11 respectively.

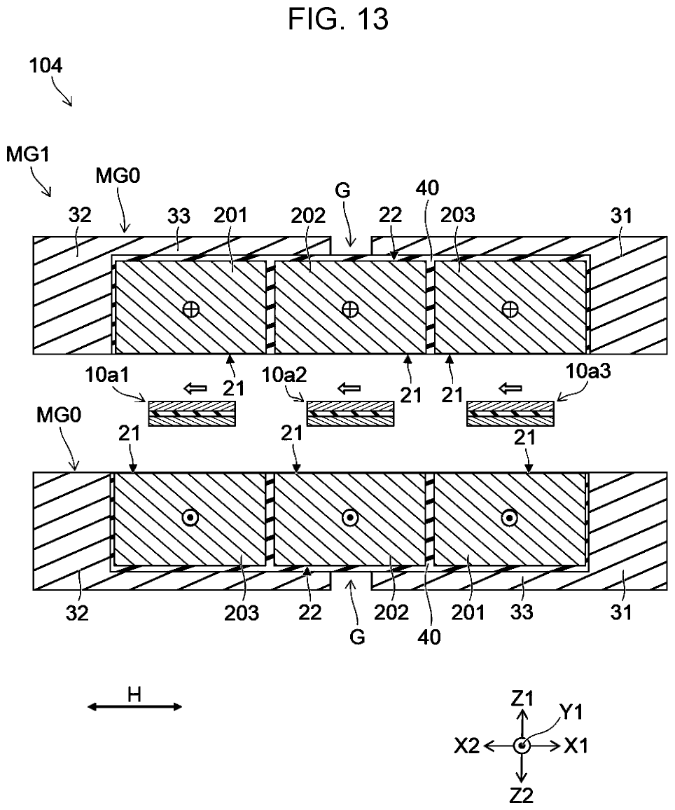

FIG. 13 illustrates still another modification of the magnetic sensor according to the embodiment. FIG. 13 is a cross-sectional view including cross sections of one magnetoresistance effect element 10a and the magnetic field generating section MG1 corresponding to the magnetoresistance effect element 10a, similarly to FIG. 2. In a magnetic sensor 104 according to the modification, similarly to the magnetic sensor 103, the magnetoresistance effect element 10a includes three magnetoresistance effect elements 10a1, 10a2, and 10a3. These magnetoresistance effect elements have the pinned magnetic layers 11 that are magnetized in the same direction (the X2 direction in the X1-X2 directions)(white arrow).

On both sides of the magnetoresistance effect element 10a1, the magnetoresistance effect element 10a2, the magnetoresistance effect element 10a3 in the second direction (Z1-Z2 direction), magnetic field generating sections MG0 are disposed. Each of the magnetic field generating sections MG0 includes three wiring line 201, wiring line 202, and wiring line 203, which are separated from each other by the insulating layer 40 and arranged in the first direction (X1-X2 direction), and the magnetically permeable section 30, which is disposed around the wiring lines. The wiring line 201 includes the first surface 21 that faces the magnetoresistance effect element 10a1 in the second direction, the wiring line 202 includes the first surface 21 that faces the magnetoresistance effect element 10a2 in the second direction, and the wiring line 203 includes the first surface 21 that faces the magnetoresistance effect element 10a3 in the second direction.

The magnetically permeable sections 30 of the magnetic field generating sections MG0 are both not disposed on the first surfaces 21 of the wiring lines 201, 202, and 203, and the magnetic gaps G are provided on the second surface 22 side of the wiring lines 202. Electric current passes to the Y2 side in the Y1-Y2 directions through the wiring lines 201, 202, and 203 of the magnetic field generating section MG0 disposed on the Z1 side in the second direction (Z1-Z2 direction). Electric current passes to the Y1 side in the Y1-Y2 directions through the wiring lines 201, 202, and 203 of the magnetic field generating section MG0 disposed on the Z2 side in the second direction (Z1-Z2 direction). This structure enables the induced magnetic fields of the wiring lines 20 to be applied to the three magnetoresistance effect elements 10a1, 10a2, and 10a3 parallel to the magnetization direction of the pinned magnetic layers 11 respectively.

FIG. 8B is a cross-sectional view illustrating a modification of the magnetic sensor according to the example 2-6. FIG. 10B is a cross-sectional view illustrating a modification of the magnetic sensor according to the example 2-7. In FIG. 8A and FIG. 10A, the magnetoresistance effect element 10a is closer to the front surface side (the Z1 side in the Z1-Z2 direction) of the substrate than the magnetic field generating section MG1 (FIG. 8A) or the magnetic field generating section MG (FIG. 10A); however, the relationship in the arrangement of the magnetoresistance effect element 10a and the magnetic field generating section MG1 (magnetic field generating section MG) is not limited to this relationship. Like a magnetic sensor 100A illustrated in FIG. 8B and a magnetic sensor 101A illustrated in FIG. 10B, in some cases, from the viewpoint of ease of manufacturing, it is preferable that the arrangement in which the magnetic field generating section MG1 (magnetic field generating section MG) be closer to the front surface side (the Z1 side in the Z1-Z2 direction) of the substrate than the magnetoresistance effect element 10a. In the magnetic sensor 100A and the magnetic sensor 101A, the first magnetically permeable portion 31, the second magnetically permeable portion 32, the third magnetically permeable portion 33, and the magnetically permeable section 30 are formed by a plating process.

1. A magnetic sensor comprising:
a magnetoresistance effect element having a sensitivity axis in a first direction, the magnetoresistance element including:
a pinned magnetic layer, a free magnetic layer, and an intermediate layer formed between the pinned magnetic layer and the free magnetic layer, which are stacked in a direction parallel to a second direction orthogonal to the first direction;
a wiring line disposed on one side of the magnetoresistance effect element in the second direction, such that an induced magnetic field generated by energizing the wiring line is applied to the magnetoresistance effect element in the first direction, the wiring line having a plurality of surfaces including a first surface facing the magnetoresistance effect element; and
a magnetically permeable section disposed on at least part of another surface other than the first surface among the plurality of surfaces of the wiring line, the magnetically permeable section formed of a ferromagnetic material.

2. The magnetic sensor according to claim 1, further comprising:
an insulating layer is disposed between the wiring line and the magnetically permeable section.

3. The magnetic sensor according to claim 2, wherein the insulating layer is a diffusion suppression layer configured to suppress interdiffusion between an element forming the wiring line and an element forming the magnetically permeable section.

4. The magnetic sensor according to claim 1, wherein the magnetically permeable section has a magnetic gap.

5. The magnetic sensor according to claim 4,
wherein the wiring line has a second surface opposite to the first surface,
and wherein the magnetic gap is provided on the second surface along a third direction orthogonal to the first direction.

6. The magnetic sensor according to claim 1,
wherein the wiring line has side surfaces opposite to each other in the first direction,
and wherein the magnetically permeable section is disposed on at least one of the side surfaces.

7. The magnetic sensor according to claim. 6,
wherein the wiring line has a second surface opposite to the first surface,
and wherein the magnetically permeable section does not extend on the second surface.

8. The magnetic sensor according to claim 7,
wherein the magnetically permeable section has an end portion in the second direction on a side of the magnetoresistance effect element,
and wherein a component of an applied external magnetic field in the second direction is converted into a component in the first direction via the end portion and thereby applied to the magnetoresistance effect element.

9. The magnetic sensor according to claim 1, wherein the wiring line and the magnetoresistance effect element are formed on a same substrate.

10. The magnetic sensor according to claim 9, wherein the first direction is one of in-plane directions of the substrate, and the second direction is a thickness direction of the substrate.
